(19) United States
(12) Patent Application Publication
(10) Pub. No.: US 2008/0299326 A1
(43) Pub. Date: Dec. 4, 2008

(54) PLASMA CVD APPARATUS HAVING NON-METAL SUSCEPTOR

(75) Inventors: Atsuki Fukazawa, Tokyo (JP); Nobuo Matsuki, Tokyo (JP); Lee Woo Jin, Tokyo (JP); Mikio Shimizu, Tokyo (JP)

Correspondence Address: KNOBBE MARTENS OLSON & BEAR LLP, 2040 MAIN STREET, FOURTEENTH FLOOR, IRVINE, CA, 92614, US

(73) Assignee: ASM JAPAN K.K., Tokyo (JP)

(21) Appl. No.: 11/755,491

(22) Filed: May 30, 2007

(51) Int. Cl. C23C 16/44

(52) U.S. Cl. 427/569; 118/723 I; 118/723 R

(57) ABSTRACT

A plasma CVD apparatus includes: a cooling susceptor for placing a substrate thereon and serving as an electrode; and a shower plate for introducing gas toward the susceptor via multiple throughholes formed therein. The shower plate serves as an electrode and is disposed in parallel to the susceptor. The cooling susceptor is made of a ceramic material provided with a cooling fluid flow path for passing a cooling fluid therethrough.

### BACKGROUND OF THE INVENTION

1. Field of the Invention

The present invention generally relates to a plasma CVD apparatus, particularly to a plasma CVD apparatus which reduces metal contamination on a substrate. Description of the Related Art

FIG. 1 is a schematic diagram of a conventional plasma CVD apparatus. Under the conventional plasma chemical vapor deposition method (plasma CVD method), a film is deposited on a semiconductor substrate inside a reaction chamber 1 in an atmosphere of 1 to 10 Torr, where a semiconductor substrate 5 to be processed is placed on a heater 3 of resistance heating type or the like heated to 0 to 350° C. The heater 3 is positioned in a manner facing a shower plate 2 that releases reactant gas, and a radio-frequency (RF) power of 13.56 MHz to 60 MHz or the like is applied to the shower plate 2 to an output level of 100 to 4000 W to cause RF discharge between the heater 3 and shower plate 2 to generate plasma. The heater 3 functions as the lower electrode, while the shower plate 2 functions as the upper electrode. The RF power applied to the shower plate 2 is supplied from an RF generator 4 through an RF supply port 7. Gas is supplied into the reaction chamber 1 through a gas supply port 6, and exhausted from an exhaust port 8. Based on this construction, an insulation film, etc., can be deposited based on the plasma CVD method. Normally, the upper and lower electrodes are primarily made of aluminum.

If a metal material is used, contamination by the metal element occurs whereby the metal deposits on the top and bottom of the silicon substrate to break the insulation layer or cause other problems, resulting in a lower device yield. This is a serious problem, and consequently the requirements for prevention of metal contamination are becoming increasingly strict as devices have finer structures. In the case of plasma CVD, in many cases an aluminum shower plate is combined with an aluminum susceptor to be used as the electrodes for generating plasma.

### SUMMARY OF THE INVENTION

In some cases where a heating susceptor is used, the materials used for the surface on which a substrate is placed, as well as other parts of the susceptor, are changed to ceramics, etc., instead of metals. However, a heating susceptor is not suitable when depositing an insulation film targeting a device node of around 50 nm. Also, the shower plate is made of metal, which leads to other problems, such as the difficulty to fully prevent metal contamination on the wafer surface. In addition, many of the components constituting the reactor are also made of metal, and therefore these other components require careful examination, as well. With many of these components, metal contamination can be prevented by coating the interior walls of the reactor with a film, called “pre-coat film,” before the deposition process is implemented. However, depositing a pre-coat film presents concerns over the long-term stability of the apparatus because the productivity drops as a result of pre-coating. On the other hand, shrinking device nodes are accelerating the development of methods to deposit an insulation film targeting a device node of around 50 nm. In particular, this trend is expected to bring significant changes to wiring patterns and STI technology, and depositing a pre-coat film will likely be met with difficulty under the new conditions anticipated. It is therefore important to prevent the negative effect of metal contamination on the substrate, without depending on deposition of pre-coat film, in conditions where an insulation film appropriate for a device node of around 50 nm is required.

In view of the foregoing, in an embodiment, the present invention provides A plasma CVD apparatus comprising: (i) a cooling susceptor for placing thereon and contacting a substrate and serving as an electrode, said cooling susceptor being made of a ceramic material provided with a cooling fluid flow path for passing a cooling fluid therethrough; and (ii) a shower plate for introducing gas toward the susceptor via multiple throughholes formed therein, said shower plate serving as an electrode and being disposed in parallel to the susceptor.

The above embodiment may further include, but may not be limited to, the following embodiments.

In any of the foregoing embodiments, the susceptor may be provided further with an RF plate embedded in the susceptor.

In any of the foregoing embodiments, the cooling fluid flow path may be provided at a bottom of the susceptor. The ceramic material constituting the susceptor may be AlN or Al₂O₃.

In any of the foregoing embodiments, the shower plate may be made of a ceramic material. The ceramic material constituting the shower plate may be AlN or Al₂O₃.

In any of the foregoing embodiments, the shower plate may have a center area which is convex.

In any of the foregoing embodiments, the susceptor may have a center area which is concave.

In any of the foregoing embodiments, the plasma CVD apparatus may further comprise a cooling fluid circulation device having a cooling fluid outlet and a cooling fluid inlet, both of which are connected to the cooling fluid flow path of the susceptor. The cooling fluid circulation device may further comprise a cooling fluid which is an aqueous solution having 10-40% ethylene glycol.

In any of the foregoing embodiments, the susceptor may include lift pins each having a surface which is exposed from the surface of the susceptor, wherein at least the surface is made of a ceramic material.

In any of the foregoing embodiments, the plasma CVD apparatus may further comprise a reaction chamber having an aluminum inner wall, in which the susceptor and the shower plate are provided in parallel.

In another aspect, the present invention provides a method of depositing a thin film on a substrate by plasma CVD, comprising: (i) providing the plasma CVD apparatus of claim 1 in a reaction chamber; (ii) controlling the susceptor at a temperature of −50° C. to 20° C.; (iii) placing a substrate on the surface of the susceptor; (iv) introducing gas into the reaction chamber through the shower plate and applying RF power to the shower plate; (v) depositing a thin film on the substrate.

The above embodiment may further include, but may not be limited to, the following embodiments.

The cooling fluid flow path may be provided at a bottom of the susceptor.

In any of the foregoing embodiments, the step of controlling the susceptor temperature may comprise circulating a cooling fluid through the cooling fluid flow path.

In any of the foregoing embodiments, the cooling fluid may be an aqueous solution having 10-40% ethylene glycol.

For purposes of summarizing the invention and the advantages achieved over the related art, certain objects and advantages of the invention are described in this disclosure. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught herein without necessarily achieving other objects or advantages as may be taught or suggested herein.

Further aspects, features and advantages of this invention will become apparent from the detailed description of the preferred embodiments which follow.

### BRIEF DESCRIPTION OF THE DRAWINGS

These and other features of this invention will now be described with reference to the drawings of preferred embodiments which are intended to illustrate and not to limit the invention. The drawings are oversimplified for illustrative purposes and are not to scale.

FIG. 1 is a schematic diagram of a conventional plasma CVD apparatus.

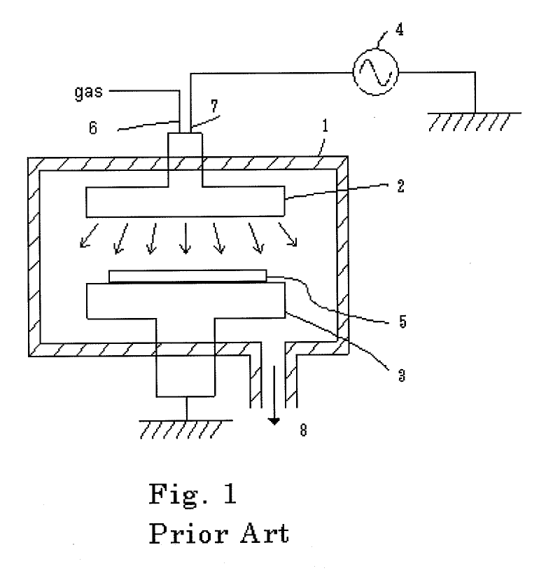

FIG. 2 is a schematic diagram of a plasma CVD apparatus according to an embodiment of the present invention.

FIG. 3 is a schematic diagram of a cross sectional view of a cooling susceptor according to an embodiment of the present invention.

FIG. 4 is a schematic diagram of a cross sectional view of a shower plate according to an embodiment of the present invention.

FIG. 5 is a schematic diagram of a cross sectional view of a susceptor according to an embodiment of the present invention (a cooling medium flow channel is not indicated).

FIG. 6 is a schematic diagram of a plasma CVD apparatus including multiple reactors and a susceptor cooling device according to an embodiment of the present invention.

FIG. 7 is a schematic diagram of a plane view of a cooling susceptor according to an embodiment of the present invention.

Explanation of symbols used is as follows: 1: Reaction chamber; 2: Upper electrode (shower plate); 3: Lower electrode (susceptor); 4: Radio-frequency (RF) generator; 5: Semiconductor substrate; 6: Gas supply port; 7: RF power supply port; 8: Exhaust port; 17: Heating device; 22: Ceramic shower plate; 24: Ceramic susceptor (cooling susceptor); 31: RF electrode; 32: Cooling medium flow channel; 33: Thermocouple; 34: Ground bar; 35: Cooling water supply pipe; 36: Cooling water circulation pipe; 37: Shaft portion; 38: Substrate supporting portion; 41: RF plate; 42: Convex area; 43: Shower plate; 51: Convex area; 53: Cooling susceptor; 61: Wafer cassette; 62: Atmospheric robot; 63: Load lock chamber; 64: Vacuum robot; 65: Cooling water circulation pipe; 66: Cooling water circulation device; 67: Mini environment; 68: Wafer transfer chamber; 69: Cooling water supply pipe; 70: Gate valve.

### DETAILED DESCRIPTION OF THE PREFERRED EMBODIMENT

As mentioned above, wiring patterns and STI technology are changing significantly as device nodes approach the 50 nm level. Especially with memory devices, application of low-k materials for insulation films, introduction of Cu wiring, and other methods are being examined with the aim of suppressing RC delay. There is also a need to reduce the dielectric constants of PMD (pre-metal dielectric) insulation films, where application of low-k materials is being examined to serve the purpose. In the meantime, embedded oxide films based on STI are also becoming narrower, and the size and aspect ratio of oxide films used today are in a range of 35 to 50 nm and around 1:20, respectively. There are reports that the conventional methods such as HDP-CVD (high-density plasma CVD) and O₃-based CVD are no longer able to achieve sufficient embedding. Accordingly, today's devices are requiring films offering good embedding property and fine size as the essential film characteristics required by wiring patterns and STI. Research is being conducted regarding a technique to form a fluid reactant on a silicon substrate, and then embed the reactant into the substrate structure by means of surface tension. To form a fluid reactant on a silicon substrate, the susceptor temperature needs to be lowered, because formation of such reactant is only possible when a reactant deposited by plasma discharge is liquefied again. To be specific, the susceptor temperature may desirably be in a range of −50 to 20° C., as sufficient embedding property cannot be achieved easily if the susceptor temperature exceeds this range. Here, the deposited film material is given a post treatment, such as heat treatment or UV curing, to be hardened and thereby made into a film. The material remains liquid, and does not exist in a film form, during the deposition stage.

Similarly, the insulation film deposited by a cooling susceptor is also in an incomplete state and is therefore weak, which makes it difficult to implement pre-coating. For this reason, in an embodiment of the present invention non-metal materials are used for the components of the reactor interior to eliminate the need for pre-coating. In an embodiment of the present invention, ceramics, such as AlN or Al₂O₃, are used to constitute the shower plate and/or cooling susceptor, in order to prevent the creation of an environment where the front and back sides of the silicon substrate will contact a metal material.

The present invention will be explained in detail with reference to preferred embodiments and drawings. However, the preferred embodiments and the drawings are not intended to limit the present invention.

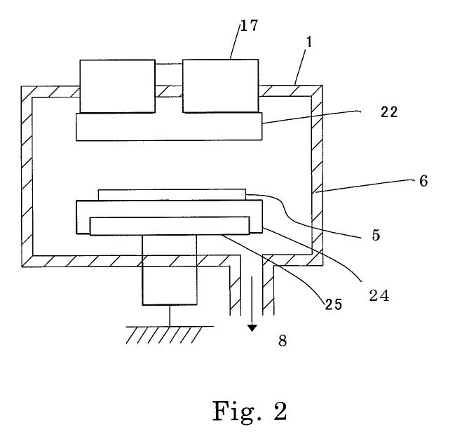

FIG. 2 is a schematic diagram of a plasma CVD apparatus according to an embodiment of the present invention (this drawing is overly simplified for the purpose of illustration). In this embodiment, a lower ceramic electrode 24 and an upper ceramic electrode 22 are positioned in parallel with each other inside a reaction chamber 1. The lower ceramic electrode 24 is a cooling susceptor and is also referred to as “cooling susceptor.” Here, the susceptor itself is made of ceramics. Also in this embodiment, a substrate is directly placed onto the susceptor, and there is no separate member or additional plate made of a different material. In an embodiment, AlN or Al₂O₃ is used as the material for the cooling susceptor, and a cooling medium flow channel 25 is formed directly inside the material. For your information, this flow channel can be formed by opening a hole in the AlN or Al₂O₃ material to create a flow channel, or connect two AlN or Al₂O₃ parts each formed with a half of the flow channel. Since the cooling susceptor also functions as the lower electrode, an RF electrode is embedded in the ceramic cooling susceptor.

On the other hand, in this embodiment the upper ceramic electrode 22 has a ceramic shower plate with an RF electrode embedded in it. The top of the ceramic shower plate has a heating device 17 to allow for control of the shower plate temperature. In an embodiment, a heater (not illustrated) is also built into the wall of the reaction chamber to allow for control of the temperature inside the reaction chamber. Although the apparatus shown in this figure has its upper and lower electrodes both made of ceramics, in an embodiment only the lower electrode may be made of ceramics.

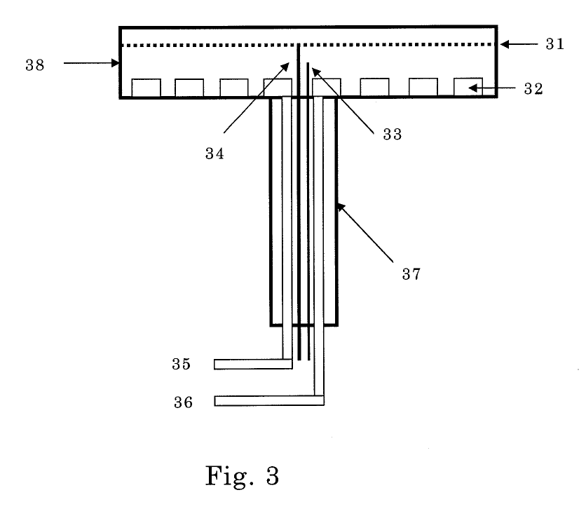

FIG. 3 is a schematic diagram of a cross sectional view of a cooling susceptor according to an embodiment of the present invention. This susceptor comprises a substrate supporting portion 38 and a shaft portion 37, and preferably the two may be constituted integrally using ceramics. In an embodiment, only the substrate supporting portion 38 may be made of ceramics. An RF plate 31 made of metal (such as tungsten or titanium) is embedded in the substrate supporting portion 38 (at a depth of 0.2 to 50 mm from the surface, for example), where the RF plate 31 may have a net-like shape, or the like, and a thickness of approx. 0.1 to 3 mm. A ground bar 34 is connected to this RF plate 31 to provide ground connection. The substrate supporting portion 38 also has a cooling water flow channel 32 (although the cooling medium is not limited to water, the term “cooling water flow channel” may be used as a matter of convenience), and the cooling water flow channel 32 is connected to a cooling water supply pipe 35 and a cooling water circulation pipe 36 provided inside the shaft portion 37, so that the cooling medium is supplied from the cooling water supply pipe 35 to the cooling water flow channel 32 in a location near the shaft portion, thereby allowing the cooling medium to circulate inside the substrate supporting portion 38 from the inside toward the outside and then finally returning to near the shaft portion to be discharged from the cooling water circulation pipe 36. By the way, the shape of the cooling water flow channel shown in FIG. 3 is approximate and overly simplified. The cooling water flow channel 32 may have a swirling shape or a shape that zigzags or meanders in the circumferential direction, for example, so that the cooling medium will circulate uniformly inside the substrate supporting portion 38. The temperature of the substrate supporting portion 38 can be measured using a thermocouple for temperature measurement 33 embedded in the ceramics (for example, at a near-center position corresponding to the center of the depth of the substrate supporting portion 38).

For your reference, in this figure the cooling water flow channel is provided at the bottom (base) of the substrate supporting portion 38 underneath the RF plate, in order to reduce uneven temperatures over the substrate supporting surface. In an embodiment, however, the cooling water flow channel may be provided at a position corresponding to the center of the depth of the substrate supporting portion 38. In an embodiment, the size of the cooling water flow channel is approx. 1 to 10 cm² in cross section. Although the cooling water flow channel has a square cross section in FIG. 3, the cross section may be a circle or oval in an embodiment.

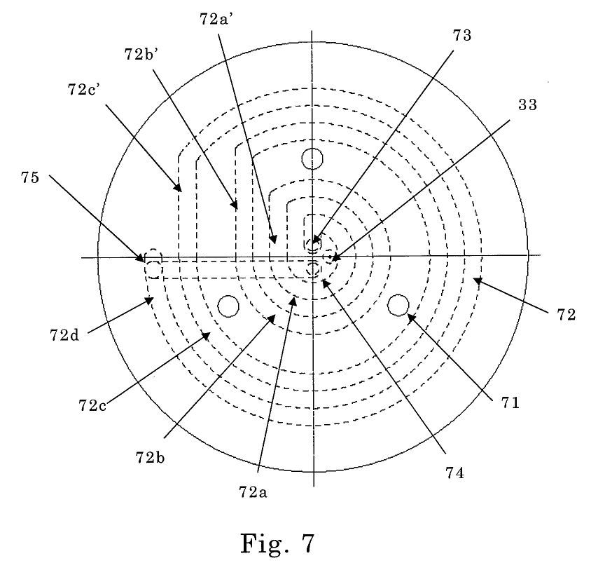

FIG. 7 is a schematic diagram of a plane view (seen from the above) of a cooling susceptor according to a different embodiment of the present invention. The cooling medium flow channel is indicated by a dotted line. This cooling medium flow channel 72 is provided in such a way that the cooling medium enters the cooling susceptor from a cooling medium inlet port 73 provided near the center, flows around roughly a swirling shape from the center toward the outside, and then exits the cooling susceptor from an outermost portion 75 through a cooling medium outlet port 74 provided near the center. When the susceptor given in this embodiment is divided into four sections on the drawing, the cooling medium flow channel maintains a constant curvature except in the top left section. To be specific, a first flow channel 72a, a second flow channel 72b, a third flow channel 72c and a fourth flow channel 72d, arranged from the center toward the outer periphery in this order, all have a constant curvature in each flow channel section. To form a swirling shape, however, in the top left section the flow channel comprises straight portions (72a′, 72b′, 72c′) and arching portions. By adopting this layout, a hole 71 for the lift pin can be avoided effectively (without reducing the cooling efficiency) (and the thermocouple for temperature measurement 33 can also be avoided effectively). The flow channel may be provided only on a single level in the thickness direction of the susceptor, but it can also be constructed to have two or more levels in an embodiment.

This flow channel can be directly formed in a ceramic susceptor without using any separate member (by, for example, using a material that will be removed after sintering the ceramics constituting the susceptor to form the portion corresponding to the flow channel, and then sintering the susceptor ceramics, or by casting one part having a concave flow channel and then connecting it to a separately formed part that becomes the base). Since the flow channel is provided directly in the ceramic susceptor, excellent heat conductivity can be achieved, which in turn leads to higher cooling efficiency. Furthermore, in this embodiment no other material but ceramics is used for the surface of the substrate supporting portion of the susceptor, which allows the surface of the substrate supporting portion (surface exposed to plasma) to be cooled effectively in a manner achieving high heat conductivity with the cooling medium.

In an embodiment, the thickness of the substrate supporting portion 38 is approx. 1.5 to 15 cm, while its diameter is approx. 33 to 40 cm. In an embodiment, the diameter of the shaft portion 37 is approx. 5 to 15 cm, while its length is approx. 15 to 40 cm.

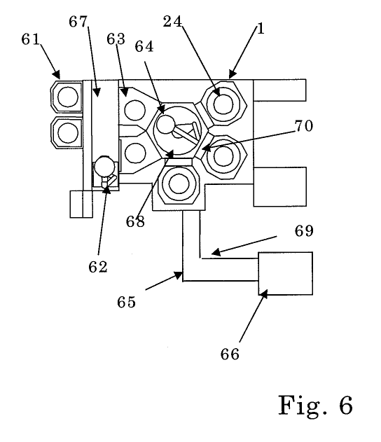

In an embodiment, the cooling medium that flows through the cooling water flow channel is a mixture of approx. 20 to 50% water and ethanol and/or ethylene glycol (for example, an ethanol solution diluted with water to 50% or lower concentrations, or ethylene glycol solution diluted with water to 60% or lower concentrations). However, the cooling medium is not limited to the aforementioned solutions, and any fluid can be used as long as its composition prevents the fluid from freezing at low temperatures while offering high specific heat and high fluidity. The concentration and material of the cooling medium can be determined in accordance with various factors, such as the temperature that needs to be lowered by cooling. In an embodiment, cooling of the cooling medium is implemented using a cooling water circulation device (such as 66 in FIG. 6 explained later) installed outside the reaction chamber 1, so that control of the cooling medium temperature is made possible. This temperature control is achieved by controlling the cooling medium temperature using the cooling water circulation device. The feed rate of the cooling medium, which has been cooled to a specific temperature, can be adjusted as necessary by monitoring the temperature of the thermocouple for temperature measurement 33 (this temperature is hereinafter referred to as “cooling susceptor temperature”). In an embodiment, the cooling susceptor temperature is adjusted to 20° C. or below, such as temperatures in a range of −50° C.to 20° C. (including −40° C., −30° C., −20° C., −10° C., 0° C., 10° C. and values between any two numbers of the foregoing). While cooling is implemented, the cooling medium controlled as above constantly flows through the flow channel to provide temperature control.

To prevent bedewing around the cooling susceptor, it is desired that the cooling susceptor temperature be kept at or above room temperature (including 25° C., 30° C., 35° C., 40° C., 45° C. and values between any two numbers of the foregoing) when the reactor is opened and closed, and this can be achieved easily by switching the cooling medium to a heating medium (such as warm water). Alternatively, the cooling susceptor temperature can be adjusted as described above by using the radiant heat from a heater provided in the interior walls of the reactor or in the shower plate. In an embodiment, desirably the temperature setting may be switched to the heating mode the moment the reactor is released to atmosphere.

In an embodiment, a non-metal material, such as AlN or Al₂O₃, is also used for the shower plate, in the same manner as for the cooling susceptor. Since metal contamination has significant impact on the silicon substrate positioned between the upper and lower electrodes where plasma discharge occurs, a preferred measure is to change the materials of both the upper and lower electrodes to a non-metal material, such as AlN or Al₂O₃, to dramatically reduce the metal contamination of the top and bottom sides of the silicon substrate. In a metal contamination study where the top and bottom sides of silicon substrates were examined after implementing the aforementioned measure, the level of metal contamination was 5.0×10¹⁰ atoms/cm² or less with all metal elements. If the upper and lower electrodes are made of aluminum, aluminum contamination of approx. 1.0×10¹² atoms/cm² occurs and this will make it difficult to use such apparatus depending on the semiconductor device manufacturing process. It will also become necessary to implement a washing process to reduce metal contamination. Many processes based on plasma CVD are used around metal wirings. In an embodiment of the present invention, metal contamination is significantly reduced and therefore film deposition by plasma CVD becomes possible with all substrate processes and wiring processes. Furthermore, in an embodiment there is no longer a need for pre-coating before the deposition process or any other traditional means for protecting the upper and lower electrodes, which not only improves productivity but also reduces the unit cost of wafer processing.

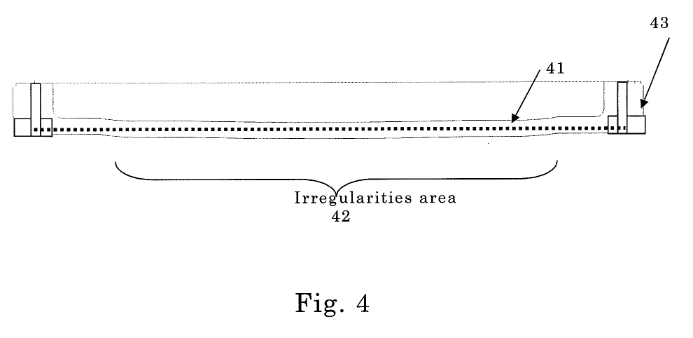

FIG. 4 is a schematic diagram of a cross sectional view of a ceramic shower plate 43 according to an embodiment of the present invention. This ceramic shower plate has an RF plate 41 embedded in it. This RF plate can basically have the same structure as the RF plate that is embedded in the ceramic susceptor. Since the shower plate has many holes (not illustrated) through which to release gas, however, the RF plate may be constructed in a manner not interfering with these holes. The ceramic shower plate has a heating device (17 in FIG. 2) to allow the shower plate temperature to be controlled within a range of approx. 50 to 250° C. In an embodiment, the thickness of the ceramic shower plate at the gas outlet is approx. 0.2 to 5 cm, while its diameter (outer periphery) is approx. 30 to 50 cm.

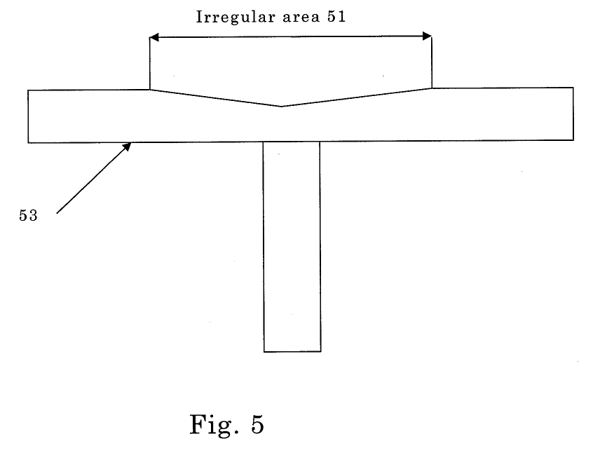

In an embodiment, the susceptor plate has a height difference on its surface in consideration of the distribution of film thickness, etc. For example, FIG. 5 provides a schematic diagram of a cross sectional view of a susceptor (a cooling water flow channel is not indicated). In FIG. 5, a susceptor 53 (for substrates of 300 mm in diameter) has a gradual concave area 51 that covers an area of 135 to 150.5 mm around the center (or 270 to 301 mm in diameter). In an embodiment, this concave area corresponds to approx. 70 to 95% (in equivalent horizontal surface area) of the substrate supporting surface (area used to support the substrate). In another embodiment, the concave area is virtually or roughly the same as the substrate. In FIG. 5, the concave area 51 inclines toward the center, with the depth at the center being 0.5 to 2 mm. In another embodiment, the entire concave area is flat and has multiple dimples so that the surface will not come in full contact with the substrate. In an embodiment, the depth of these dimples is 40 to 80 μm.

As for the shower plate, in an embodiment the distribution of film thickness is controlled in the same manner as with the susceptor by means of the number of holes arranged in a circular pattern as well as a height difference on the surface. For example, a schematic diagram of a surface shape is shown in FIG. 4. In FIG. 4, a gradual convex area 42 is provided on the shower plate surface to cover 20000 to 69000 mm² around the center, where this area corresponds to approx. 25 to 90% of the front face of the shower plate. In another embodiment, the convex area occupies an area corresponding to approx. 25 to 90% (in equivalent horizontal surface area) of the front face of the shower plate. In an embodiment, the center height of the convex area is approx. 0.5 to 6 mm when measured from the outer periphery of the shower plate. Note, however, that in many cases a flat shower plate is used as a standard specification.

As mentioned above, it is effective to use non-metal materials, such as AlN and Al₂O₃, in areas that come in contact with the wafer in order to reduce metal contamination. Constituting the upper and lower electrodes with non-metal materials is also effective when the gas flow around the electrodes is considered, in that the area between the upper and lower electrodes is subject to active species generated by plasma reaction. If the upper electrode is made of a metal material, gases flowing down from the upper electrode come in contact with the metal, and this leads to attachment of metal contaminants. Accordingly, not only the lower electrode but also the upper electrode needs to be made of a non-metal material.

The method of film deposition by plasma CVD was already explained in the example of a conventional apparatus. Specifically, the gas introduced into the reactor through the shower plate reacts with the plasma discharged between the shower plate and susceptor, which respectively constitute the upper and lower electrodes, and the reactant is deposited onto the silicon substrate. Thereafter, the gas is guided by the exhaust plate to flow into the exhaust line, travels to the dry pump, and eventually gets discharged. The cooling susceptor plate is cooled by means of controlling the cooling medium flowing inside the cooling susceptor. The temperature of the susceptor plate is detected by the thermocouple installed in the susceptor. Temperature control is implemented by introducing the cooling medium, which is controlled by the cooling water circulation device, into the susceptor via the flow channel.

FIG. 6 is a schematic diagram of a plasma CVD apparatus according to an embodiment of the present invention. In this figure, three reaction chambers 1 are connected to a substrate transfer chamber 68 via a gate valve 70. Two load lock chambers 63 are also connected to the substrate transfer chamber 68. The load lock chamber 63 is connected to a substrate cassette 61 via a mini environment 67. A substrate is transferred into the load lock chamber 63 from the substrate cassette 61 by means of an atmospheric robot 62 located in the mini environment 67, and then further transferred by means of a vacuum robot 64 located in the substrate transfer chamber 68 into each reaction chamber 1 where the substrate will be processed. The cooling susceptor 24 is provided in the reaction chamber 1, and this cooling susceptor 24 is connected to a cooling water circulation device 66 so that a cooling medium is supplied from a cooling water circulation device 66 through a cooling medium supply pipe 69 to be circulated inside the cooling susceptor, and eventually returned to the cooling water circulation device 66 through a cooling medium circulation pipe 65.

For your reference, although AlN and Al₂O₃ are mainly used as ceramic materials, BN and other materials can also be used in an embodiment.

In the present disclosure where conditions and/or structures are not specified, the skilled artisan in the art can readily provide such conditions and/or structures, in view of the present disclosure, as a matter of routine experimentation.

Also, in the present disclosure, the numerical numbers applied in embodiments can be modified by ±50% in other embodiments, and the ranges applied in embodiments may include or exclude the endpoints.

### EXAMPLE

The present invention will be explained with reference to Examples. However, the Examples are not intended to limit the present invention. In the Examples, as a plasma CVD apparatus, Eagle®10 (ASM Japan) was used except for the susceptor and shower plate specified in the Examples.

### Conventional Example

The susceptor, shower plate and film deposition conditions used herein are as follows:

Shower plate material: Aluminum

Susceptor material: Aluminum

Susceptor temperature: 0° C.

Shower plate temperature: 100° C.

Reactor side wall temperature: 100° C.

DM-DMOS flow rate: 25 sccm

Hexane flow rate: 80 sccm

He flow rate: 630 sccm

O₂ flow rate: 100 sccm

Reactor pressure: 400 Pa

Discharge gap: 20 mm

As a result of operation under the aforementioned conditions, the following levels of metal contamination were detected (based on ICP-MS evaluation). For your reference, the standard is 5×10¹⁰ atoms/cm² or less for each element. “Others” indicates the sum of metal elements such as nickel and manganese.

Aluminum: 1×10¹³ atoms/cm²

Titanium: 3×10¹¹ atoms/cm²

Chromium: 8.5×10¹⁰ atoms/cm²

Others: 5×10¹⁰ atoms/cm² or less

As shown above, although the metal contamination level of other metal elements was around the standard, the metal contamination levels of aluminum, titanium and chromium all exceeded the standard and metal contamination was confirmed. Here, the metals thus detected are assumed to be due to the upper and lower electrodes.

### Example 1

The susceptor, shower plate and film deposition conditions used herein are as follows:

Shower plate material: AlN

Cooling susceptor material: AlN

Susceptor temperature: 0° C.

Shower plate temperature: 100° C.

Reactor side wall temperature: 100° C.

DM-DMOS flow rate: 25 sccm

Hexane flow rate: 80 sccm

He flow rate: 630 sccm

O₂ flow rate: 100 sccm

Reactor pressure: 266 Pa

Discharge gap: 20 mm

As a result of operation under the aforementioned conditions, the following levels of metal contamination were detected (based on ICP-MS evaluation). For your reference, the standard is 5×10¹⁰ atoms/cm² or less for each element. “Others” indicates the sum of metal elements such as iron, chromium, titanium and nickel.

Aluminum: 4.5×10¹⁰ atoms/cm²

Others: 5×10¹⁰ atoms/cm² or less

As shown above, there were significant improvements in metal contamination levels. In particular, aluminum contamination decreased by an order of three.

### Example 2

The susceptor, shower plate and film deposition conditions used herein are as follows:

Shower plate material: AlN

Cooling susceptor material: AlN

Susceptor temperature: 0° C.

Shower plate temperature: 100° C.

Reactor side wall temperature: 100° C.

DM-DMOS flow rate: 25 sccm

Hexane flow rate: 80 sccm

He flow rate: 830 sccm

O₂ flow rate: 100 sccm

Reactor pressure: 800 Pa

Discharge gap: 20 mm

As a result of operation under the aforementioned conditions, the following levels of metal contamination were detected (based on ICP-MS evaluation). For your reference, the standard is 5×10¹⁰ atoms/cm or less for each element. “Others” indicates the sum of metal elements such as titanium and chromium.

Aluminum: 3×10¹⁰ atoms/cm²

Others: 5×10¹⁰ atoms/cm² or less

As shown above, there were significant improvements in metal contamination levels. In particular, aluminum contamination decreased by an order of three.

It will be understood by those of skill in the art that numerous and various modifications can be made without departing from the spirit of the present invention. Therefore, it should be clearly understood that the forms of the present invention are illustrative only and are not intended to limit the scope of the present invention.

What is claimed is:

1. A plasma CVD apparatus comprising:
a cooling susceptor for placing thereon and contacting a substrate and serving as an electrode, said cooling susceptor being made of a ceramic material provided with a cooling fluid flow path for passing a cooling fluid therethrough; and
a shower plate for introducing gas toward the susceptor via multiple throughholes formed therein, said shower plate serving as an electrode and being disposed in parallel to the susceptor.

2. The plasma CVD apparatus according to claim 1, wherein the susceptor is provided further with an RF plate embedded in the susceptor.

3. The plasma CVD apparatus according to claim 1, wherein the shower plate is made of a ceramic material.

4. The plasma CVD apparatus according to claim 1, wherein the cooling fluid flow path is provided at a bottom of the susceptor.

5. The plasma CVD apparatus according to claim 1, wherein the ceramic material constituting the susceptor is AlN or Al₂O₃.

6. The plasma CVD apparatus according to claim 3, wherein the ceramic material constituting the shower plate is AlN or Al₂O₃.

7. The plasma CVD apparatus according to claim 1, wherein the shower plate has a center area which is convex.

8. The plasma CVD apparatus according to claim 1, wherein the susceptor has a center area which is concave.

9. The plasma CVD apparatus according to claim 1, further comprising a cooling fluid circulation device having a cooling fluid outlet and a cooling fluid inlet, both of which are connected to the cooling fluid flow path of the susceptor.

10. The plasma CVD apparatus according to claim 9, wherein the cooling fluid circulation device further comprises a cooling fluid which is an aqueous solution having 10-40% ethylene glycol.

11. The plasma CVD apparatus according to claim 1, wherein the susceptor includes lift pins each having a surface which is exposed from the surface of the susceptor, wherein at least the surface is made of a ceramic material.

12. The plasma CVD apparatus according to claim 1, further comprising a reaction chamber having an aluminum inner wall, in which the susceptor and the shower plate are provided in parallel.

13. A method of depositing a thin film on a substrate by plasma CVD, comprising:
providing the plasma CVD apparatus of claim 1 in a reaction chamber;
controlling the susceptor at a temperature of −50° C. to 20° C.;
placing a substrate on the surface of the susceptor;
introducing gas into the reaction chamber through the shower plate and applying RF power to the shower plate;
depositing a thin film on the substrate.

14. The method according to claim 13, wherein the cooling fluid flow path is provided at a bottom of the susceptor.

15. The method according to claim 14, wherein the step of controlling the susceptor temperature comprises circulating a cooling fluid through the cooling fluid flow path.

16. The method according to claim 15, wherein the cooling fluid is an aqueous solution having 10-40% ethylene glycol.
